(19) United States
(12) Patent Application Publication
(10) Pub. No.: US 2004/0256246 A1
(43) Pub. Date: Dec. 23, 2004

(54) Electrode pad for debonding paint from a nonconductive surface

(76) Inventors: Rudolf Keller, Murrysville, PA (US); Brian J. Barca, Munhall, PA (US)

Correspondence Address: ANDREW ALEXANDER & ASSOCIATES, 3124 KIPP AVENUE, P.O. BOX 2038, LOWER BURRELL, PA, 15068, US

(21) Appl. No.: 10/872,068

(22) Filed: Jun. 18, 2004

Related U.S. Application Data
(60) Provisional application No. 60/480,639, filed on Jun. 23, 2003.

(51) Int. Cl. B01J 2/00; C30B 7/12; C30B 9/14

(52) U.S. Cl. 205/687

(57) ABSTRACT

A method of electrolytically debonding a paint coating from an electrically nonconductive member wherein the paint coating is bonded to a surface of the nonconductive member. The method comprises providing an electrode blanket on the paint coating, the electrode blanket comprised of a first blanket layer in contact with the paint coating, a negative electrode layer in contact with the first blanket layer, a second blanket layer covering the negative electrode layer, a positive electrode layer in contact with the second blanket layer, and a third blanket layer covering the positive electrode layer. An aqueous-based electrolyte solution is applied to the electrode blanket. An electric current is passed from the negative electrode to the positive electrode, evolving hydrogen at the negative electrode, thus creating an alkaline condition thereby causing delamination and degrading of the paint coating on the electrically nonconductive member.

### BACKGROUND OF THE INVENTION

This invention relates to paint removal and more particularly it relates to a method and apparatus for removing paint from surfaces of nonconductive substrates.

Prior methods of removing paint from large surfaces of a nonconductive substrate such as wood or concrete involved chemical stripping, scraping, heat gun treatment, or abrasive techniques. However, any abrasive action or burning has the problem that large amounts of fragment paint, fine dust and fumes become airborne. This is particularly hazardous when the paint contains heavy metal compounds such as lead and chromate.

Environmental regulations provide for stringent controls on the amount of metal such as lead that can escape into the atmosphere or onto surface soil and water. Contamination of water with lead paint is particularly troublesome because the metals in the paint can find their way into drinking water. To avoid this type of contamination when abrasive blasting, for example, attempts have been made to use enclosures around the structures to be depainted. However, such enclosures tend to be awkward and costly to use and often do not contain the abrasive and paint particles sufficiently well. Thus, hazardous quantities of the lead can still escape into the atmosphere and find their way to the soil and drinking water.

Another area of concern is in the removal of paint from wood in confined areas, e.g., in the interior of buildings where airborne particles (dust) are not acceptable. In addition, abrasive techniques present occupational hazards, and personnel must be protected from inhaling and contacting toxic paint constituents. Thus, in order to avoid contamination of the environment, abrasive methods require expensive precautions in an attempt to comply with environmental and health regulations. In the case of plastic media blasting of paints, chromate contaminates the blasting media, making disposal an environmental problem.

Another approach to removing paint coatings from wood structures involves the use of organic solvents or caustic solutions for chemical stripping. While the solvents can be effective in removing paint, they contaminate the environment upon evaporation and the escape of volatile organic compounds is restricted by law. Further, solvents have the problem of disposal after being used. The use of caustic solutions has the disadvantage that they are hazardous and require long and weather-dependent soak times to be effective. Thus, there is a great need for a system that avoids these problems.

In U.S. Pat. No. 6,030,519, incorporated herein by reference, there is disclosed a method of electrolytically separating a paint coating from a metal surface comprising the steps of providing a metal member having a surface having a paint coating thereon and contacting the member with an essentially neutral electrolytic solution. The metal member is made cathodic in an electrolytic cell and current is passed from an anode electrode pad through the electrolytic solution to the metal member for a time sufficient to cause the paint coating to separate from the metal member. The pad is comprised of a first blanket for contacting the paint coating, a second blanket to cover the first blanket and an electrode mesh positioned between the first and second blankets.

In U.S. Pat. No. 5,507,926, incorporated herein by reference, there is disclosed a method of electrolytically separating paint coating from a metal surface comprising the steps of providing a metal member having a surface having a paint coating thereon and contacting the member with an essentially neutral electrolytic solution. The metal member is made cathodic in an electrolytic cell and current is passed from an anode through the electrolytic solution to the metal member for a time sufficient to cause the paint coating to separate from the metal member. However, it was discovered that such process, while efficient, resulted in areas where debonding did not occur. Thus, there is a great need for an improved process which will operate to uniformly remove or separate the paint coating from the substrate.

In prior work, the use of electrochemical processes has been suggested for cleaning of metals. For example, Dunn U.S. Pat. No. 1,917,022 suggests the use of an electrochemical process for cleaning metal wherein the work is subjected to electrolytic action in a simple non-cyanide alkaline bath in the presence of metallic ions. According to Dunn, the work may be made either anode or cathode and in either case the dirt is subjected to three distinct cleaning actions; namely, the chemical detergent effect of the alkaline solution; the saponification and emulsification effect; and the mechanical action resulting from the liberation of gases at the work surface. Further, Dunn notes that while the metallic ion concentration may be inaugurated and maintained by the addition to the electrolyte of metal salts such as salts of lead, tin, zinc or cadmium, it is preferred to introduce ions by anodic action on the electrodes. According to Dunn, certain metals will have characteristic advantages and disadvantages. In the case of lead, lead peroxide forms at the anode and with the use of tin, metastannic acid forms. However, the Dunn reference has the disadvantage that it requires an alkaline bath and the addition of heavy metal ions such as lead or cadmium, further aggravating the environmental problem.

U.S. Pat. No. 3,900,376 discloses cleaning metal surfaces of elongated metal articles such as rods, bars, strips and wire. The metal articles are passed through an electrolyte such that a gas, e.g., hydrogen, is evolved at the metal surface. A high voltage is applied between the article and an inert anode such that the surface of the article in the electrolyte is completely covered by gas and vapor through which a discharge passes. However, the operation has to be carried out in the region of the current minimum of the current/voltage characteristic which occurs beyond the normal electrolysis regime as the voltage is increased. According to the Patent, the high voltage and high current density cause substantial heat generation and the surface of the article is covered with a layer containing both hydrogen and steam. The discharge through the gas and vapor layer causes any scale on the article to flake off.

U.S. Pat. No. 2,765,267 discloses a process for stripping flexible films of resin which adhere to underlying metal bases to produce unsupported dielectric layers. The insulating layers are removed from the underlying bases by an electrolytic process in which the base metal is made the cathode in an electrolytic cell, and the insulating layer is forced off the base metal by the pressure of gaseous hydrogen at the junction between the metal and insulation, a distinctly different action than used in the present invention.

U.S. Pat. No. 3,457,151 discloses cleaning of an article made of conductive and nonconductive materials such as a printed circuit board, in an electrolytic bath and causing a current to flow in the bath between a cathodic element closely adjacent the board and an anodic element. The scrubbing action of the hydrogen bubbles generated at the cathodic element and at the conductive portions of the board cleans all of the surfaces.

U.S. Pat. No. 3,823,080 discloses an electrolytic process for removing a coating from a cathode ray tube mask member, and U.S. Pat. No. 4,439,289 discloses an electrolytic method for removal of magnetic coatings from computer memory disc using a sulfuric acid and glycerin solution.

ASTM Designation G95-87, “Standard Test Method for Cathodic Disbondment Test of Pipeline Coatings” and ASTM Designation G8-90 “Standard Test Methods for Cathodic Disbonding of Pipeline Coatings” disclose test methods that cover accelerated procedures for simultaneously determining comparative characteristics of insulating coating systems applied to steel pipe exterior for the purpose of preventing or mitigating corrosion that may occur in underground service where the pipe will be in contact with inland soils and may or may not receive cathodic protection.

Other electrolytic cleaning methods are disclosed in U.S. Pat. Nos. 4,493,756; 5,104,501 and 5,232,563. However, it will be seen that there is still a great need for a process for removing paint coatings from nonconductive surfaces such as wood and cement, which does not permit contamination of the environment with heavy metal components such as lead or chromium compounds contained in the protective coating.

### SUMMARY OF THE INVENTION

It is an object of the invention to provide a process for removing paint coatings from nonconductive substrates.

It is another object of the invention to provide an improved electrolytically assisted process for removing paint coatings from nonconductive surfaces.

Yet, it is another object of the invention to provide an improved electrolytic process for removing paint coatings from nonconductive surfaces using an electrolyte solution with a substantially neutral pH.

And yet, it is another object of the invention to provide an improved electrolytic process for removing paint coatings from nonconductive surfaces which avoids contamination of the environment with caustic or organic chemicals or heavy metals contained in airborne paint dust.

It is still another object of the invention to provide an electrode blanket or pad for electrolytically assisted paint removal from a nonconductive surface.

It is yet another object of the invention to provide an improved electrode blanket or pad which facilitates more uniform removal of paint from nonconductive substrates using the electrical process of the invention.

These and other objects will become apparent from a reading of the specification and claims appended hereto.

In accordance with these objects, there is provided a method of electrolytically removing a paint coating from an electrically nonconductive member wherein the paint coating is bonded to a surface of the nonconductive member. The method comprises providing an electrode blanket on the paint coating, the electrode blanket comprised of a first blanket layer in contact with the paint coating, a negative electrode layer in contact with the first blanket layer, a second blanket layer covering the negative electrode layer, a positive electrode layer in contact with the second blanket layer, and a third blanket layer covering the positive electrode layer. An aqueous-based electrolyte solution is applied to the electrode blanket. An electric current is passed from the positive electrode to the negative electrode, evolving hydrogen at the negative electrode, creating an alkaline condition thereby causing delamination and degrading of the paint coating on the electrically nonconductive member.

Modifications may include the substitution or addition of materials such as filter paper, ionic membranes, additional absorbent layers, or direct physical contact of surface by negative electrode.

### BRIEF DESCRIPTION OF THE DRAWINGS

FIG. 1 is a flow chart illustrating steps in the invention.

FIG. 2 shows a painted nonconductive substrate having the contacting electrolyte contained in a layer or blanket in contact with the nonconductive substrate.

FIG. 3 shows an improved electrode pad or blanket for forming an electrolyte cell in conjunction with a painted nonconductive surface.

FIG. 4 illustrates a cross section of the improved blanket of FIG. 3 along the line III-III.

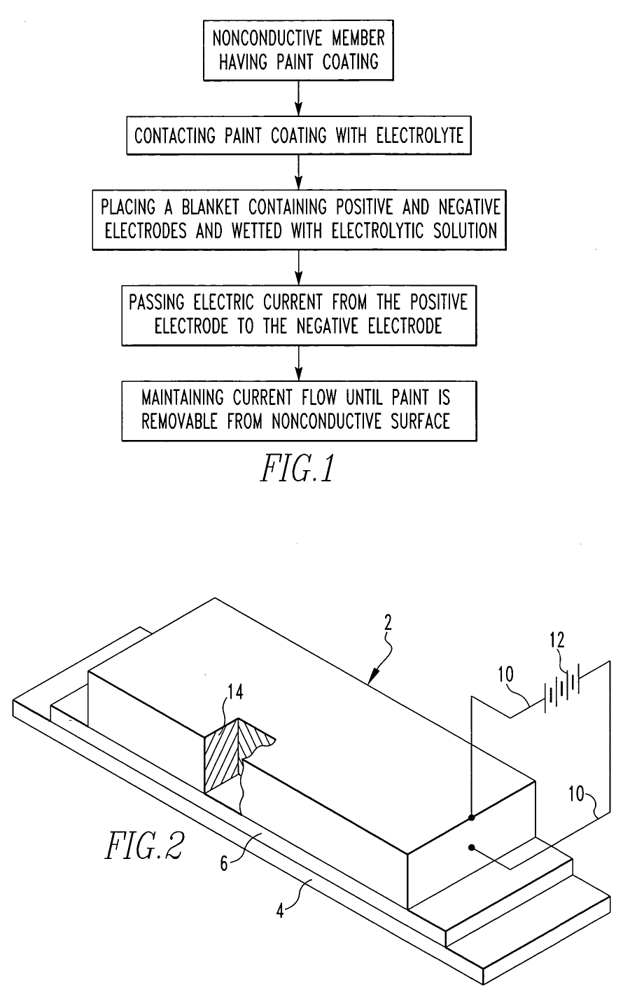

### DETAILED DESCRIPTION OF PREFERRED EMBODIMENTS

The present invention has particular application to painted structures such as wooden houses, inside and outside brick, or mortar walls because it assures the absence of dust emissions which is prevalent with the use of abrasive methods. Further, the present invention is particularly suitable for removal of paints from such houses or structures thereby containing the removed paint constituents without fear of contaminating soil, surface water or air with heavy metals such as lead which may be contained in such paint. It will be appreciated that older structures often contain lead in paints and such paints can still be present on such structures even if re-painted since often it was commonplace to paint over the old paint coatings. In the present invention, there is no need for special equipment and special procedures usually needed for abrasive techniques, enclosures to contain the dust inherent in abrasive methods, or the use of dust masks by personnel conducting the paint removal operation. Further, the present invention is highly suitable for use in confined spaces such as the interior of houses or buildings such as rooms.

Briefly, in the present invention, the nonconductive surface from which paint is to be removed is contacted with an electrolytic solution. A blanket or pad as shown in FIG. 2 is provided with both an anode and a cathode to form an electrolytic cell. Electrolytic solution is applied to the pad, and current is passed between the anode and cathode for a time sufficient to cause the paint to degrade and be removable from the nonconductive surface (FIG. 2).

For purposes of the present invention, the electrolytic solution can be any water-based electrolytic solution that is compatible with the nonconductive substrate containing the paint coatings to be removed. The pH of the solution can range from very acidic, e.g., pH of 1 or 2, to very alkaline, e.g., pH of 12 or 13. In certain instances, it is preferred that the solution is utilized at a substantially neutral unbuffered pH and does not contain any metals that can be cathodically reduced in appreciable quantities. Thus, the electrolyte of the present invention does not further contaminate the environment by the use of heavy metals and the like. The electrolyte can comprise a material selected from Na₂ SO₄, K₂ SO₄, Na₃ PO₄, K₃ PO₄ and NaCl. Preferably, the electrolyte is comprised of single salt. While the electrolyte can be highly alkaline, the preferred electrolyte is substantially neutral. Further, preferably, the electrolyte is a chloride-free electrolyte.

The material can be present in the electrolytic solution in the range of 0.01 to 3 mols/l and preferably in the range of 0.1 to 0.7 mols/1 with a typical amount being about 0.4 to 0.6 mols/l to provide for the required levels of conductivity.

Preferably, the electrolytic solution has a substantially neutral pH. However, the electrolytic solution can have a pH in the range of 3 to 10 and preferably a pH in the range of about 5 to 9. Typically, the pH ranges from about 6 to 8. By the term “substantially neutral pH” is meant a pH range of 3 to 10, preferably 5 to 9 and typically 6 to 8.

The temperature at which the method can be used can range from −5 to 60° C., but preferably the electrolytic solution is used at or about ambient temperature. Thus, it will be seen that the method has the advantage that it is not sensitive to weather conditions above freezing.

While the inventors do not wish to be bound by any theory of invention, it is believed that the degradation or the debonding or paing is primarily chemical in nature. The cathodic reaction such as hydrogen evolution causes a localized higher pH which reacts to degrade the coating. Debonding or degrading is not primarily caused by stirring or other physical action as occasioned by gas evolution.

As noted, the nonconductive surface from which the paint coating is separated and removed is contacted on the surface by the electrolytic solution. When the degrading or debonding of the paint surface of a large object, such as a building, is required to be performed in situ, the contact of the surface with electrolyte may be accomplished utilizing a blanket 2 (FIG. 2) saturated with electrolytic solution. In FIG. 2, there is shown a painted nonconductive substrate 4 having a pad or blanket 2 in contact therewith. Blanket 2 may be comprised of any absorbent material that can be saturated with electrolytic solution such that electric current can be passed through the electrolyte. Examples of such blanket materials include: SORB-X, available from Matarah Industries, Inc., Milwaukee, Wis., or other spill control materials or other “hydrophyllic” blanket materials such as those available from SPC, Somerset, N.J., or sponge mats available from BREG International, Fredericksburg, Va., all referred to herein as blanket material. As shown in FIG. 2, blanket 2 may have a paper or cloth layer 6 permeable by the electrolyte. Further, paper or cloth layer 6 may have a surface thereof coated with an adhesive which contacts the paint coating. Thus, when the paint coating degrades, residue becomes firmly attached to the adhesive. After treatment, the paper layer may be removed with paint fragments to be processed for recovery of metals in the paint. Gaps 14 may be incorporated in larger size blankets to facilitate escape of gas, if the cathodic reaction produces gas such as hydrogen. In addition, blanket 2 is provided with electrode meshes 8 and 9 such as a wire mesh which can serve as an anode and cathode. The anode and cathode are connected by electrical connectors 10 to an electric power source 12 which supplies DC current to the electrodes. It is preferred that electrode mesh 8 be comprised of a flexible material to permit blanket 2 to be wrapped around sharp structures such as door jams. Blanket 2 may be held in contact with the painted nonconductive surface by any means that permits electrolytic communication with the painted surface. Fasteners or other type retainers may be utilized to bring the blanket in contact with the surface.

The anode and cathode may be comprised of any material that permits electrical contact with the electrolyte and permits passage of current. Thus, the anode and cathode may comprise a metal mesh such as a steel, nickel, stainless steel, graphite screen or cloth, titanium or other suitable materials. A suitable material is expanded low-carbon steel sheet available from Exmet Corporation, Nangatuck, Conn.

It will be appreciated that a wide range of electrolytes can be used in conjunction with blanket 2 because substantially all of the electrolytic compounds are contained in blanket 2 during the debonding operation. Thus, almost any suitable electrolyte, including sea water, is contemplated for use with blanket 2. Further, the bonding operation can be carried out to remove paint coatings from any nonconductive substrate.

When the electrolyte is in contact with the painted surface, a current density is passed at a rate that promotes debonding or delamination of the paint coating from the nonconductive surface. Thus, a current density in the range of 100 to 2000 amps/m² may be used with a preferred current density being in the range of 500 to 1000 amps/M².

The time for which the electric current is applied can vary depending on the paint coating and the difficulty of debonding. Thus, the time for which the electric current is applied is that which causes sufficient degradation. Such times can range from 5 to 150 minutes, preferably 5 to 60 minutes.

After the paint coating debonds, it can be collected and processed in a controlled manner to permit recovery of heavy metals.

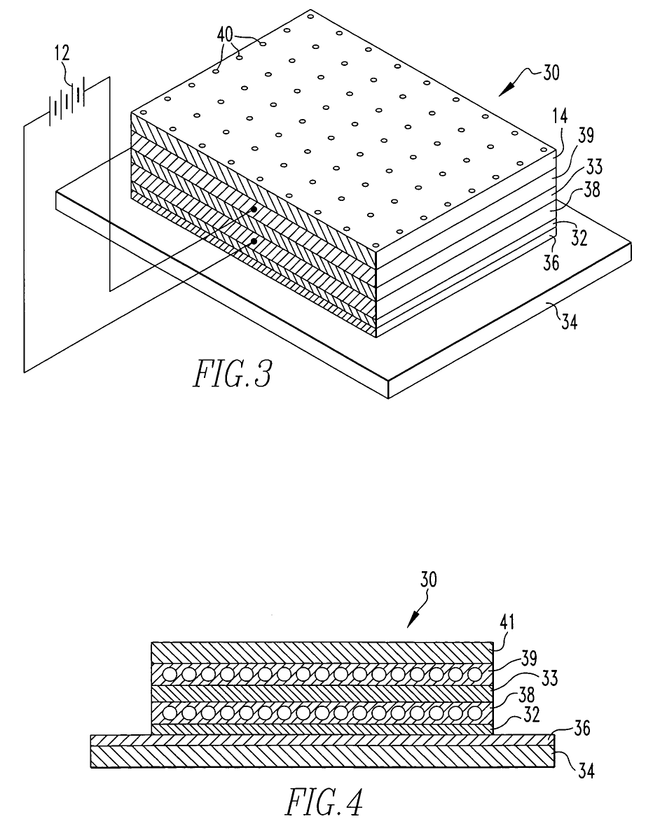

In another aspect of the invention, an improved pad or blanket, referred to herein as an electrode pad or blanket 30, is provided as shown in FIGS. 3 and 4. In FIG. 3 there is shown a nonconductive substrate 34 having a layer of paint thereon. Positioned on substrate 34 is an electrode pad or blanket 32 comprised of several layers to facilitate uniform removal or debonding of paint adhering to the substrate. The electrode pad or blanket can comprise a paper or cloth layer 36 permeable by electrolyte. As noted earlier, paper or cloth layer 36 may have the surface in contact with the paint surface coated with an adhesive. Thus, after the debonding treatment, the paint layer is removed with the paper.

In this aspect of the invention, electrode blanket 30 is comprised of a first blanket or pad 32 provided on one side electrode mesh 38 and a second blanket or pad 33 which is provided on the opposite or outside of electrode mesh 38, except in areas reserved to apply the current connection. On top of layer 33 is provided another electrode mesh 39 which is covered with blanket layer 41. It will be appreciated that blankets 32, 33 and 41 serve to envelope electrode meshes 38 and 39. As will be seen from FIGS. 3 and 4, electrode pad or blanket 30 is preferably provided with perforations 40 to facilitate removal of gases such as oxygen away from anode 39 and hydrogen away from cathode 38. It is important to remove gases to prevent explosions resulting from mixing of hydrogen and oxygen, for example. By electrode mesh is meant a series of wires, for example, which may cross each other or a series of wires which may be placed parallel to each other or arranged randomly to provide a continuous conductive element. Any arrangement of members can be used to provide a conductive medium.

Electrode pad or blanket 30, comprising pads or blankets 32, 33 and 41, is an important aspect of the subject invention because it permits uniform removal of paint coatings or layers from nonconductive substrates. The pads can be of varying thicknesses and the inside pad can be as thin as filter paper or the negative electrode can be placed in contact with the paint coating. That is, inside pad 32 can range in thickness from about the same or equal thickness as pad 33 or 41 to about 10 times thicker. It should be understood that if pad 32 is permitted to exceed a certain thickness, the resistance becomes too great, thus interfering with the effectiveness of debonding the paint coating. In a preferred embodiment, inside pad 32 is about one and one-half (1-½) to four (4) times as thick as pads 33 or 41. It should be noted that pads 32, 33 and 41 may be fastened to electrode meshes 38 and 39 with suitable fasteners (not shown) to facilitate handling.

Outside pad 41 has the advantage that it prevents dry spots occurring in inside pad 32 under operation and thus sacrificially gives up liquid to inside pad 32. Presently, it is not fully understood how the dry spots occur. Dry spots result in non-uniform removal or debonding of pain coatings from the substrate. That is, when electrolyte is not present on portions of pad 32, paint is not removed or debonded in that area, requiring further work to remove such paint. It has been discovered that an electrode pad comprising outside pad 41 substantially eliminates premature occurrence of dry spots and greatly aids in the uniform removal of paint coatings.

In another aspect of the invention, it is preferred that the edges of the pads extend slightly beyond the edges of electrode meshes 38 and 41 to prevent adjacent pads from shorting on each other.

While the invention has been described with respect to nonconductive surfaces, it should be understood that the invention can be applied to other conductive members such as graphite, carbon-carbon composites, and carbon-epoxy composites or other electrically conductive materials having paint coatings thereon such as used in aircraft. The invention has a special advantage when used with such conductive materials because of the low temperature of application, for example, not exceeding 100° C.

### EXAMPLE 1

Paint was removed from a 6″×12″ area of a square-shaped brick pillar. The modified ElectroPad was secured to this brick pillar. The pad consisted of two electrode steel screens and liquid-absorbent material between the screens and on the outside. Direct current was passed for 1.5 hours from the outer screen to the inner screen. 80% of the paint coating was removed. A pH of <4 was determined on the outer part of the ElectroPad and >10 on the underside.

### EXAMPLE 2

This test was conducted on a piece of window molding covered with a multi-layered lead-containing paint coating. The ElectroPad, 2-½×4 inch in size, was deformed to fit the surface of the molding. The pad arrangement contained two electrode screens separated by absorbent material, with another layer of absorbent material placed on the outside. Direct current of 10 Amp was passed from one electrode to the other for one hour and 20 minutes, and 90% of the paint became readily removable. The pH determined under the pad arrangement was >13. This alkaline condition evidently leads to the degrading of the paint.

Thus, it will be seen from the examples that paint coatings can be removed effectively from nonconductive substrates providing a paint-free nonconductive surface. The paint fragments are easily collected for proper disposal.

While the invention has been described in terms of preferred embodiments, the claims appended hereto are intended to encompass other embodiments which fall within the spirit of the invention.

What is claimed is:

1. A method of electrolytically debonding or degrading a paint coating from an electrically nonconductive member wherein the paint coating is bonded to a surface of the nonconductive member, the method comprising:
(a) providing an electrode blanket on said paint coating, said electrode blanket comprised of:
(i) a first blanket layer in contact with said paint coating;
(ii) a negative electrode layer in contact with said first blanket layer;
(iii) a second blanket layer covering said negative electrode layer;
(iv) a positive electrode layer in contact with said second blanket layer; and
(v) a third blanket layer covering said positive electrode layer;
(b) applying an aqueous-based electrolyte solution to electrode blanket; and
(c) passing an electric current from positive electrode to said negative electrode, evolving hydrogen at said negative electrode creating an alkaline condition thereby causing delamination and degrading of said paint coating on said electrically nonconductive member.

2. The method of electrolytically removing a paint coating from an electrically nonconductive surface in accordance with claim 1 including passing the current at a current density in the range of 500 to 1000 amps/m².

3. The method in accordance with claim 1 wherein said solution contains an environmentally benign electrolyte selected from the group consisting of Na₂ S0₄, K₂ S0₄, Na₃ PO₄, K₃ PO₄ and NaCl.

4. The method in accordance with claim 3 wherein the solution contains 0.01 to 3 mols/l electrolyte.

5. The method in accordance with claim 1 wherein the solution contains Na₂ S0₄.

6. The method in accordance with claim 1 including maintaining the bulk electrolyte solution in pH range of 3 to 10.

7. The method in accordance with claim 1 including maintaining the bulk electrolyte solution in a pH range of 6 to 8.

8. The method in accordance with claim 1 including maintaining the bulk electrolyte solution in a pH range of 6.5 to 7.5.

9. The method in accordance with claim 1 including employing an electrolyte solution from about ambient temperature up to 100° C.

10. A method of electrolytically debonding a paint coating from an electrically nonconductive member wherein the paint coating is bonded to a surface of the nonconductive member, the method comprising:
(a) providing an electrode blanket on said paint coating, said electrode blanket comprised of:
(i) a negative electrode layer in contact with said paint coating;
(ii) a first blanket layer covering said negative electrode layer;
(iii) a positive electrode layer in contact with said first blanket layer; and
(iv) a second blanket layer covering said positive electrode layer;
(b) applying an aqueous-based electrolyte solution to electrode blanket; and
(c) passing an electric current from positive electrode to said negative electrode, evolving hydrogen at said negative electrode creating an alkaline condition thereby causing delamination and degrading of said paint coating on said electrically nonconductive member.

11. The method in accordance with claim 10 including providing a blanket layer between said paint coating and said negative electrode layer.

12. The method in accordance with claim 10 including providing a filter paper layer between said paint coating and said negative electrode layer.

13. The method in accordance with claim 10 including placing the negative electrode in contact with said paint coating.
